(19) United States
(12) Patent Application Publication
(10) Pub. No.: US 2012/0258266 A1
(43) Pub. Date: Oct. 11, 2012

(54) Coatings For Engine And Powertrain Components To Prevent Buildup Of Deposits

(75) Inventors: Wieland Koban, Mannheim (DE); Dirk A. Großschmidt, Mannheim (DE); Michael P. Galligan, Cranford, NJ (US); Christopher R. Castellano, Ringoes, NJ (US); Alexander Gorel, Hillsborough, NJ (US); Kenneth E. Voss, Somerville, NJ (US)

(73) Assignee: BASF Corporation, Florham Park, NJ (US)

(21) Appl. No.: 13/439,288

(22) Filed: Apr. 4, 2012

Related U.S. Application Data
(60) Provisional application No. 61/472,318, filed on Apr. 6, 2011.

(51) Int. Cl. B05D 5/00; B05D 1/36; C23C 4/08; C23C 16/06; B32B 9/00; B05D 1/18

(52) U.S. Cl. 428/34.1; 428/697; 428/457; 427/436; 427/455; 427/456; 427/250; 427/405

(57) ABSTRACT

Provided are methods and components related to preventing hydrocarbon residue buildup in engine components. Prevention is achieved using a coating of a mixed metal oxide. The mixed metal oxide comprises a mixture of at least two of Gd, Al, Ti, Ce, Pr, La, Y, Nd, and Mn. The coating can also contain amounts of precious metals, eg. Pt, Pd, Rh and/or Au.

### CROSS-REFERENCES TO RELATED APPLICATIONS

This application claims priority under 35 U.S.C. §119(e) to Provisional U.S. Patent Application No. 61/472,318, filed Apr. 6, 2011, which is hereby incorporated by reference in its entirety.

### TECHNICAL FIELD

The invention relates generally to the field of combustion engines, and specifically to coatings for preventing hydrocarbon residue buildup on engine and/or powertrain components.

### BACKGROUND

Internal combustion piston engines with carburetion or fuel injection are very well known. These engines usually have several cylinders, where an axially-moving piston encloses a combustion chamber. In these combustion chambers, combustion of a fuel-air mixture fed into the combustion chamber occurs.

A pervasive problem of these internal combustion engines is the formation of carbonization residues from unburnt fuel and lubrication oil fed to the engine. These residues are bituminous and, in part, highly complex mixtures of hydrocarbons. The residues are deposited and accumulate on various engine and powertrain structural components. This includes valves, piston surfaces, intake ports, injection nozzles, and the upper surface of the combustion chamber. These carbonization residues may accumulate to such an extent, especially on intake valves, that they produce undesired changes in the fluid dynamics or closing behavior of the valve. Carbonization residues can also have very negative effects on other component surfaces of the combustion chamber (e.g., the piston working surfaces). Another frequently encountered problem is deposit build up on turbochargers, mainly the compressor housing. This is particularly problematic for engines with positive crankcase ventilation. Thus, there is a need for methods and compositions for preventing such buildup.

### SUMMARY

Embodiments of the invention pertains to providing a coating of mixed metal oxides comprising at least two of Al, Ti, Gd, Ce, Pr, La, Y, Nd and Mn. Specific embodiments pertain a coating comprising a mixture of Al, Ce, Zr, La, Pr, and Pd.

Accordingly, one aspect of the invention relates to an article comprising an engine or powertrain component and a coating applied to the engine or powertrain component, the coating comprising a mixed metal oxide, the mixed metal oxide comprising Ce, Pr, Al, Zr and La. In one embodiment, the engine or powertrain component is selected from the group consisting of turbocharger, valve, piston, piston fireland, firedeck, compressor housing, intake port, injection nozzle, combustion chamber, shroud, swirl generator and combinations thereof.

In another embodiment of this aspect, the coating further comprises a precious metal. In a further embodiment, the precious metal comprises Pd. In yet another embodiment, the coating is catalytically active. In a specific embodiment, the coating comprises Pd in the range of 1% to 5% by weight and ceria in the range of 5% to 60% by weight on a oxide basis, and oxides of rare earth metals in the range of 5-20% by weight on an oxide basis. In another variant, the coating further comprises lanthanum oxide and zirconia in an amount of about 50% by weight on an oxide basis. In a very specific embodiment, the coating comprises about 3 wt % Pd, about 30% ceria, about 7 wt % oxides of Pr and La, about 40 wt % zirconia, and about 20 wt % alumina.

Another aspect of the invention relates to a method of preventing hydrocarbon deposit buildup on engine or powertrain components, the method comprising applying a coating on an engine or powertrain component, the coating comprising a mixed metal oxide, the mixed metal oxide comprising at least two metals selected from the group consisting of Gd, Al, Ti, Ce, Pr, La, Y, Nd, Mn, Zr and combinations thereof. In one embodiment, the engine or powertrain component is selected from the group consisting of turbocharger, valve, piston, piston fireland, firedeck, compressor housing, intake port, injection nozzle, combustion chamber and combinations thereof. In one or more embodiments, the coating is applied by dip coating, thermal spraying, plasma spraying, airbrushing, impregnation, atomic layer deposition or combinations thereof.

In another embodiment, the coating further comprises a precious metal. In other variants, a Ni/Al bond-coat is used. In yet other variants, the coating is applied to a metallic surface of the engine or powertrain component.

In other embodiments still, the coating is catalytically active to prevent carbonization residue, or the coating is modified by post-deposition or post-impregnation thereby providing the precious metal on the surface of the coating. In a very specific embodiment, the coating comprises about 3 wt % Pd, about 30% ceria, about 7 wt % oxides of Pr and La, about 40 wt % zirconia, and about 20 wt % alumina.

### BRIEF DESCRIPTION OF THE DRAWINGS

FIG. 1 is a graph showing combustion product CO obtained on samples coated with catalyst and uncoated samples;

FIG. 2 is a graph showing combustion product CO₂ obtained on samples coated with catalyst and uncoated samples;

FIG. 3 is a graph showing combustion product CO obtained on samples coated in accordance with one or more embodiments of the invention and a comparative sample; and

FIG. 4 is a graph showing combustion product CO₂ obtained on samples coated in accordance with one or more embodiments of the invention and a comparative sample.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Residue buildup occurs as a result from unburned hydrocarbons, lubricant oil and soot. The problem of residue buildup can occur on the surfaces of various engine and/or powertrain components, including, but not limited to the turbocharger, valve, piston, piston fireland, firedeck, compressor housing, intake port, injection nozzle, shroud, swirl generator and combustion chamber. In one or more embodiments, the component has grooves or indentations on the surface of the component.

Accordingly, one aspect of the invention relates to a coating that prevents deposit buildup on engine and powertrain components. One embodiment of the invention pertains to an article component comprising an engine or powertrain component and a coating applied to the engine or powertrain component. Without a coating, the engine or powertrain component would have at least some of its surface exposed to hydrocarbons. In one embodiment, the coating is applied to a component that is on the intake side of a turbocharger, as opposed to the exhaust side.

One or more embodiments of the invention provide a coating that prevent deposit buildup from occurring. That is, the residue that normally accumulates on the surface of various engine and/or powertrain components never has the opportunity to collect on these surfaces. While not wishing to be bound to a particular theory, it is thought that the coating helps combust the residues at low temperatures. It is thought that the coating does not work as a simple repellant.

The coating comprises a mixed metal oxide, which is comprised of at least two metals selected from the group consisting of Al, Ti, Gd, Ce, Pr, La, Y, Nd, Zr and Mn. In another embodiment, the coating also comprises a precious metal, for example, Pt, Pd, Rh and/or Au. In one or more embodiments, the coating is catalytically active to remove hydrocarbon deposits on engine components. In a specific embodiment, the coating comprises Pd and another component selected from those provided above. In a further embodiment, the coating comprises Pd in the range of 1% to 5% by weight and ceria in the range of 5% to 60% by weight on a oxide basis, and oxides of rare earth metals in the range of 5-20% by weight on an oxide basis.

In another embodiment, the coating comprises a mixed metal oxide, the mixed metal oxide comprising Ce, Pr, Al and La. In a further embodiment, the coating comprises about 3 wt % Pd, about 30% ceria, about 7 wt % oxides of Pr and La, about 40 wt % zirconia, and about 20 wt % alumina.

According to one or more embodiments, the metal oxides are in particulate form. In specific embodiments, particles of high surface area, e.g., from about 100 to 500 square meters per gram (“m² /g”) surface area, specifically from about 150 to 450 m²/g, more specifically from about 200 to 400 m²/g, are desired so as to better disperse the catalytic metal component or components thereon. The first layer refractory metal oxide also desirably is mesoporous and has a high porosity of pores up to 1456 Angstroms radius, e.g., from about 0.75 to 1.5 cubic centimeters per gram (“cc/g”), specifically from about 0.9 to 1.2 cc/g, and a pore size range of at least about 50% of the porosity being provided by pores of 50 to 1000 Angstroms in radius. For alumina particles, it may be desirable to utilize a high surface area mesoporous gamma alumina, for example GA-200.

Another aspect of the invention relates to a method of preventing residue buildup. One embodiment pertains to a method of preventing hydrocarbon deposit buildup on engine or powertrain components, the method comprising applying a coating on an engine or powertrain component, the coating comprising a mixed metal oxide, the mixed metal oxide comprising at least two metals selected from the group consisting of Al, Ti, Ce, Pr, La, Y, Nd, Mn, Zr and combinations thereof. In a further embodiment, the applied coating further comprises a precious metal.

The coating may be applied to any deposit-prone engine or powertrain component including, but not limited to, the turbocharger, valve, piston, piston fireland, compressor housing, intake port, injection nozzle and combustion chamber. In a specific embodiment, the coating is applied to a metallic surface of the engine or powertrain component.

The coatings described herein may be applied using a variety of methods. Various methods of application include, but are not limited to, dip coating, thermal spraying, plasma spraying, airbrushing, impregnation, and atomic layer deposition. In one embodiment, the coating is applied via suspension plasma spraying. In another embodiment, a Ni/Al bond-coat may be used to enhance thermal stability of coating. In another embodiment, a post-deposition or post-impregnation process may be used to enhance the coating. In order to reduce the overall precious metal content of the coating, post-impregnation can be used such that the precious metal would be present at the surface only. The other ceramic layer would only provide the surface adhesion to the metal, like a bond coat. Generally speaking, a slurry which meets the proper solids % content and rheology can be loaded into an apparatus which utilizes pressurized air to generate a spray pattern consisting of fine droplets. This apparatus could be one of a few different units, including, but not limited to: paint spray guns, glass mist sprayers, and pressurized spray bottles. The apparatus used can have various settings adjusted to control the droplet size, spray pattern/shape, and amount of slurry sprayed per unit of time. The method could involve multiple passes with the spray gun, and could involve drying and/or calcining between coatings. Different layers can also be applied in this fashion. Another method that can be employed is dipping the substrate into a slurry, then using an air knife to blow off excess slurry until a desired coating is attained.

In one embodiment, the coating is applied using a suspension plasma technique. This technique comprises suspending a mixed metal oxide in a suspension; atomizing the slurry with suspended mixed metal oxide into a suspension plasma as described further below; and spraying the suspension plasma onto a engine, exhaust-gas-system or powertrain component. Optionally, the suspension plasma may be sprayed only onto the surface of the engine, exhaust-gas-system or powertrain component that is prone to residue buildup.

Exemplary suspension plasma spray methods according to one or more embodiments involve several process steps. First, solid particles are dispersed into a liquid and kept in suspension during the process. Second, the suspension is fed and injected into a heat source. Next, the solid particles in suspension are at least partially melted and impact on a surface of an article to form a deposit. The heat source in plasma spraying can include, but is not limited to electric arc plasma, RF plasma or microwave plasma. Suitable examples of suspension plasma spraying are described in U.S. Pat. Nos. 5,609,921, 6,277,448, and 4,376,010, the entire content of each patent being incorporated herein by reference.

Suspension plasma spraying, according to one or more embodiments, involves a plasma spray deposition method for producing a material deposit onto a substrate. The method can comprise producing a plasma discharge; providing a suspension of a material to be deposited, this suspension comprising small solid particles of that material dispersed into a liquid or semi-liquid carrier substance; atomizing the suspension into a stream of fine droplets and injecting the stream of fine droplets within the plasma discharge; and by means of the plasma discharge, (a) vaporizing the carrier substance, (b) agglomerating the small particles into at least partially melted drops, (c) accelerating these drops, and (d) projecting the accelerated drops onto the substrate to form the material deposit.

The probe atomizes the suspension into a stream of fine droplets and injects this stream of droplets generally centrally of the plasma discharge. The suspension is then sheared and thereby atomized, and injected in the plasma discharge under the form of fine droplets through the opening. Although an example of suspension plasma spraying process and apparatus have been described hereinabove, the present invention is not limited to the process as apparatus described, and alternative atomizing processes are available to shear the suspension.

The stream of fine droplets travels through the plasma discharge to reach the substrate. As the droplets of suspension travel from the opening to the substrate, these droplets are subjected to several physicochemical transformations. The suspension is typically composed of small solid particles suspended and dispersed into a solvent or other liquid or semi-liquid carrier substance. When the fine droplets of suspension reach the plasma discharge, the solvent first evaporates and the vapor thus formed decomposes under the extreme heat of the plasma. The remaining aerosol of small solid particles then agglomerate into drops which are either totally or partially melted and/or vaporized. The plasma discharge accelerates the molten drops, which accumulate kinetic energy. Carried by this kinetic energy, the drops hit the substrate. The plurality of drops form on the substrate a layer of partially or totally melted drops partially overlapping one another.

### COMPARATIVE EXAMPLE 1

A coating of pure aluminum was prepared on a test planchette. The test planchette consists of pure aluminum, and is free of any coating. It thus serves as a comparative example, and is representative of, for example, a turbocharger aluminum surface.

### EXAMPLE 2

A coating was deposited on a planchette via air spray. A slurry which met the proper solids % content and rheology was loaded into an apparatus which utilizes pressurized air to generate a spray pattern consisting of fine droplets. The coating included a mixed oxide of Ce, Zr, La, and Gd oxides. The composition was as follows: 31% Ce, 45%Zr, 10% Y, 14% (La+Gd).

### Testing of Examples

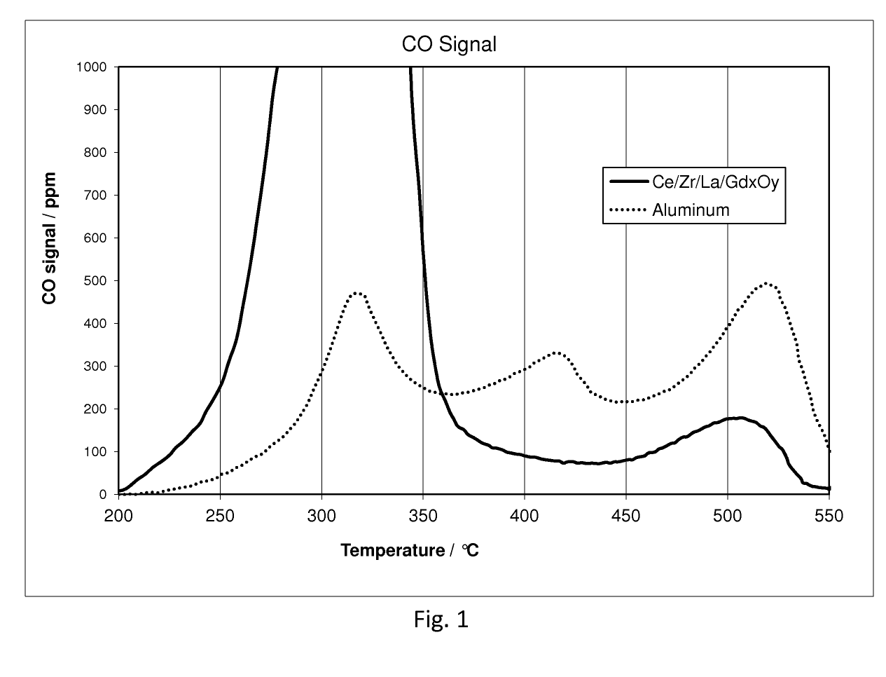

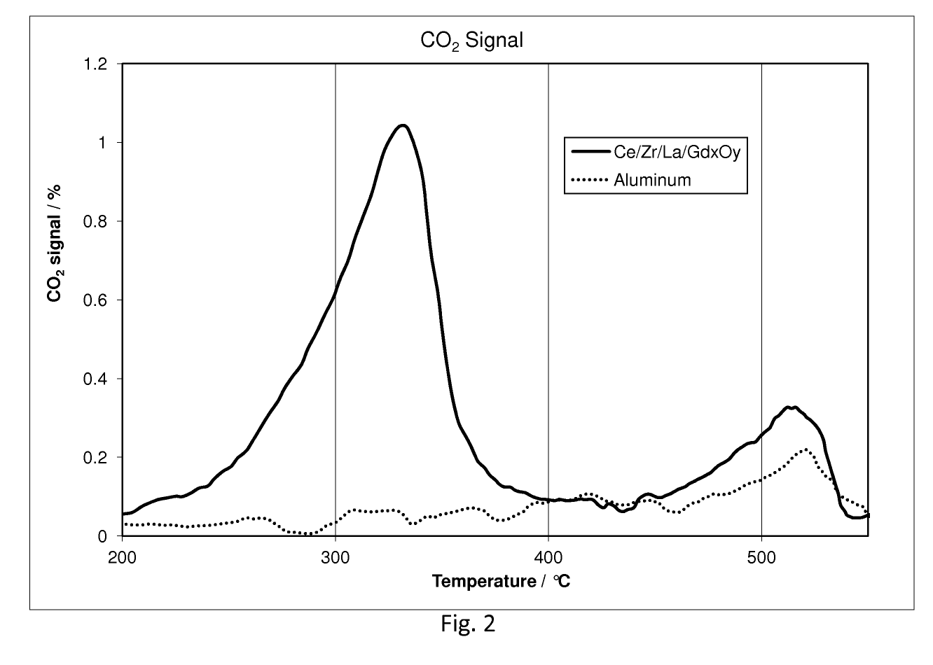

On the planchette, soot and oil were applied to the surface, and a temperature ramp was applied in air. Combustion product CO and CO₂ development were measured. Planchettes with soot/oil mixture on the surface of the planchettes were placed in a furnace. The furnace was ramp in temperature at 15 K/min. The gas temperature right above the planchettes was measured by means of an additional type K thermocouple. The gases above the planchettes are extracted with a nozzle. This gas was analyzed for CO and CO₂ using an Uras 14, Advance Optima module from ABB which uses infrared light. From this measurement, the catalytic activity of the coating for hydrocarbon oxidation was deduced. In FIG. 1 the CO signal is displayed, and in FIG. 2 the CO₂ signal is shown. In FIG. 1, which shows the CO signal, there are three peaks developing over temperature for the aluminum planchette are present. The first peak reflects lube oil burning, the third peak reflects soot burning, but the second peak, however, around 400° C. reflects the burning of oil residues. No such second peak is apparent for a catalytic surface made from mixed Ce, Zr, La, Gd oxide Thus, no oil residue deposits are formed in this case. The explanation can be seen in FIG. 2. A strong CO₂ signal is apparent for the catalyst-coated surface. This reflects the complete combustion of the oil components. On the contrary, no CO₂ signal is shown on the uncoated aluminum surface. The oil is combusted incompletely, and residues of partially burned or cracked hydrocarbons remain on the pure aluminum surface.

### EXAMPLES 3-7

Example 3. A sample of 3% Pd, 30% Ceria, 7% rare earth oxides (Pr oxide and La oxide), 40% zirconia, and 20% alumina was deposited on a planchette via a suspension plasma spray.

Example 4. A coating of 1% Pd, 1% Pt and the remainder alumina was deposited on a planchette.

Example 5. A coating of 3% Pt, 70% Ceria and the remainder alumina was deposited on a planchette.

Example 6. A coating of 1% Pt, 70% Ceria and the remainder alumina

Comparative Example 7. A coating of 100% zirconia was deposited on a planchette. This example is considered to be a reference sample for inactive coatings because Zr is generally inactive.

### Testing of Examples 3-7

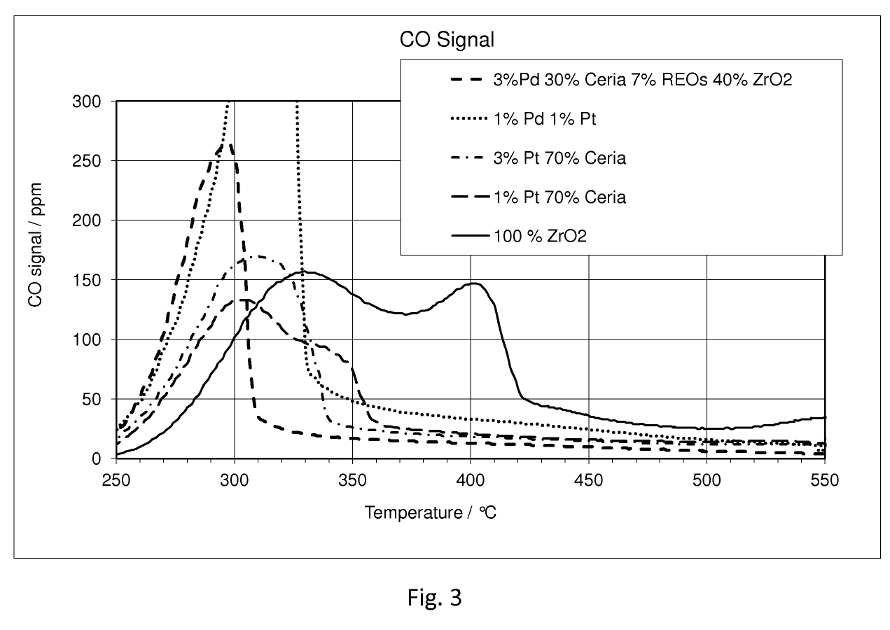

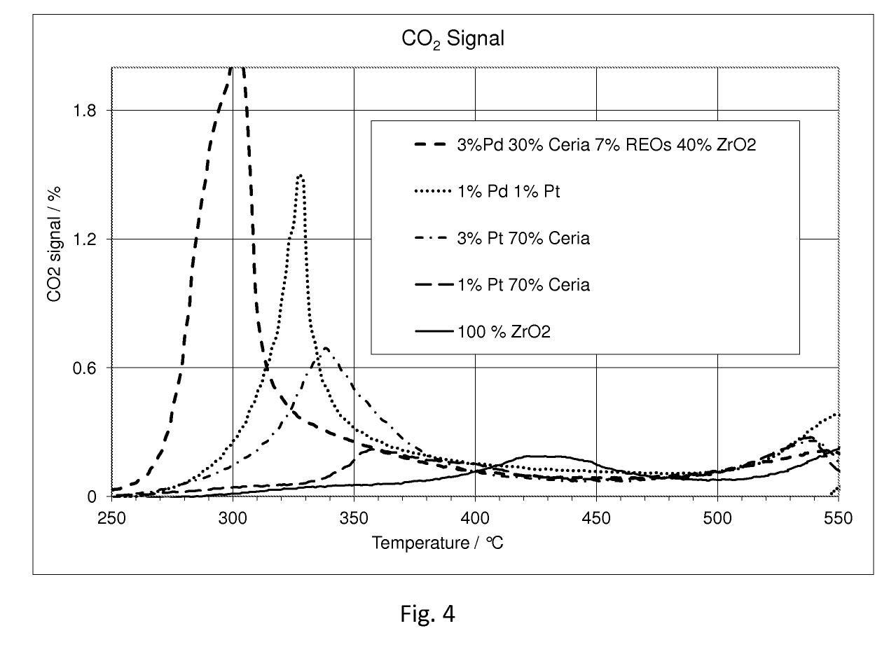

Testing was conducted similarly as above, and results are shown in FIGS. 3 and 4. The inclusion of Pd shows very promising results. Examples 3 and 4, the Pd-containing samples, have the lowest oil burning peak temperatures and show the highest oxidation activity. In the CO signal, it can be seen that the oxidation reaction starts below 250° C. and in the CO₂ signal, it can be seen that oxidation peaks at around 300° C. for the Pd-containing samples. While the absolute temperatures of this test cannot be necessarily compared to real world applications, the tests above show temperature shift in lowering the burning temperature for hydrocarbon deposited on the planchettes. Carbon buildup is prevented by burning off hydrocarbon. In engine applications, for instance, the oil loading will be much lower in the final application. However, the results are very valuable to compare the relative performance of the samples for oil oxidation and hence their ability to prevent deposit formation. Zirconia is widely inactive as can be seen in the low CO₂-signal intensity.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. An article comprising:
a. an engine or powertrain component;
b. a coating applied to the engine or powertrain component, the coating comprising a mixed metal oxide, the mixed metal oxide comprising Ce, Pr, Al, Zr and La.

2. The article of claim 1, wherein the engine or powertrain component is selected from the group consisting of turbocharger, valve, piston, piston fireland, firedeck, compressor housing, intake port, injection nozzle, combustion chamber, shroud, swirl generator and combinations thereof.

3. The article component of claim 1, wherein the coating further comprises a precious metal.

4. The article component of claim 3, wherein the precious metal comprises Pd.

5. The article component of claim 1, wherein the coating is catalytically active.

6. The article of claim 4, wherein the coating comprises Pd in the range of 1% to 5% by weight and ceria in the range of 5% to 60% by weight on a oxide basis, and oxides of rare earth metals in the range of 5-20% by weight on an oxide basis.

7. The article of claim 1, wherein the coating further comprises lanthanum oxide and zirconia in an amount of about 50% by weight on an oxide basis.

8. The article of claim 7, wherein the coating comprises about 3 wt % Pd, about 30% ceria, about 7 wt % oxides of Pr and La, about 40 wt % zirconia, and about 20 wt % alumina.

9. A method of preventing hydrocarbon deposit buildup on engine or powertrain components, the method comprising applying a coating on an engine or powertrain component, the coating comprising a mixed metal oxide, the mixed metal oxide comprising at least two metals selected from the group consisting of Gd, Al, Ti, Ce, Pr, La, Y, Nd, Mn, Zr and combinations thereof.

10. The method of claim 9 wherein the engine or powertrain component is selected from the group consisting of turbocharger, valve, piston, piston fireland, firedeck, compressor housing, intake port, injection nozzle, combustion chamber and combinations thereof.

11. The method of claim 9, wherein the coating further comprises a precious metal.

12. The method of claim 9, wherein the coating is applied by dip coating, thermal spraying, plasma spraying, airbrushing, impregnation, atomic layer deposition or combinations thereof.

13. The method of claim 9, wherein a Ni/Al bond-coat is used.

14. The method of claim 9, wherein the coating is applied to a metallic surface of the engine or powertrain component.

15. The method of claim 9, wherein the coating is catalytically active to prevent carbonization residue.

16. The method of claim 9, wherein the coating is modified by post-deposition or post-impregnation thereby providing the precious metal on the surface of the coating.

17. The method of claim 9, wherein the coating comprises about 3 wt % Pd, about 30% ceria, about 7 wt % oxides of Pr and La, about 40 wt % zirconia, and about 20 wt % alumina.
